(19) United States
(12) Patent Application Publication
(10) Pub. No.: US 2010/0218803 A1
(43) Pub. Date: Sep. 2, 2010

(54) Non-planar photocell

(75) Inventor: Robert E. Maltby, JR., Wayne, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/779,824

(22) Filed: May 13, 2010

Related U.S. Application Data
(62) Division of application No. 10/704,139, filed on Nov. 10, 2003.

(51) Int. Cl. H01L 31/042

(52) U.S. Cl. 136/244

(57) ABSTRACT

A photovoltaic cell having a substrate with at least one curved surface reduces the number of processing steps necessary to manufacture a completed cell. Such a photovoltaic cell can have semiconductor material on the outer surface of a curved substrate or on the inner surface of a curved substrate.

### CLAIM OF PRIORITY

This is a divisional application of U.S. application Ser. No. 10/704,139 filed on Nov. 10, 2003, which is incorporated by reference in its entirety.

### TECHNICAL FIELD

This invention relates to energy collection, and more particularly to photovoltaic energy cells.

### BACKGROUND

Photovoltaic devices have been developed based on crystalline silicon, which requires a relatively thick film such as on the order of about 100 microns and also must be of very high quality in either a single-crystal form or very close to a single crystal in order to function effectively. The most common process for making silicon photovoltaic cells is by the single-crystal process where a flat single-crystal silicon wafer is used to form the device. In addition, crystalline silicon can be made by casting of an ingot but its solidification is not as easily controlled as with single-crystal cylinders such that the resultant product is a polycrystalline structure. Direct manufacturing of crystalline silicon ribbons has also been performed with good quality as well as eliminating the necessity of cutting wafers to make photovoltaic devices. Another approach referred to as melt spinning involves pouring molten silicon onto a spinning disk so as to spread outwardly into a narrow mold with the desired shape and thickness. High rotational speeds with melt spinning increase the rate of formation but at the deterioration of crystal quality. More recent photovoltaic development has involved thin films that have a thickness less than 10 microns so as to be an order of magnitude thinner than thick film semiconductors. Thin film semiconductors can include amorphous silicon, copper indium diselenide, gallium arsenide, copper sulfide and cadmium telluride. These semiconductors have primarily been formed on glass sheet substrates. The glass sheet substrates have been limited in size in order to maintain the planarity of the resultant photovoltaic cell. Furthermore, formation of the photovoltaic cells involves an extensive number of processing steps to ensure adequate formation and functionality of the final cells. Additionally, after fully formed the glass sheet photovoltaic cells are not insignificant in weight, requiring sturdy mounting assemblies.

### SUMMARY

In one aspect a photovoltaic cell includes a substrate having a curved surface and a first semiconductor material on the surface. The curved surface can be concave or convex. The substrate can have a polygonal cross-section and can be formed from glass, low iron glass, low expansion glass, borosilicate glass, other types of glass or other materials suitable for use as substrates for photovoltaic cells.

A photovoltaic cell can include a bottom layer between the curved surface and the first semiconductor material. The bottom layer can include a conductive material. The conductive material can be a transparent conductive layer and can be a transparent conductive oxide. In one aspect the conductive material can be a tin oxide. In another aspect a photovoltaic cell can include a second semiconductor material between the first semiconductor material and the top layer. The second semiconductor material can be a binary semiconductor such as a Group II-VI semiconductor. The first semiconductor material can be CdS and the second semiconductor material can be CdTe.

In still another aspect a photovoltaic cell can include a buffer layer in contact with the bottom layer and between the bottom layer and the first semiconductor material. A photovoltaic cell can include a top layer covering at least a portion of the first semiconductor material and the top layer can include a metal or an alloy.

A photovoltaic cell can have an electrical conductor electrically connected to the bottom layer and an electrical conductor connected to the top layer.

In one embodiment a photovoltaic cell can have a substrate with an annular cross section that includes a first end, a second end opposite the first end, an inner surface connecting the first end and the second end, and an outer surface opposite the inner surface.

In another aspect a photovoltaic cell can have a substrate in the form of a glass tube and semiconductor material can be on a portion of the inner surface of the substrate. The photovoltaic cell can include a first electrical connection connected to a top layer and a second electrical connection connected to the bottom layer. The first end can form a seal around the first electrical connection and can form a seal around the second electrical connection such that the inner surface, the first end and the second end form a chamber. The chamber can contain a gas or gas mixture having a pressure less than atmospheric pressure and the chamber can contain an inert gas such as helium, argon, nitrogen, or a combination thereof.

In another embodiment a photovoltaic cell can have the first semiconductor material on a portion of the outer surface of the substrate.

In another aspect, a method of making a photovoltaic cell includes forming a coating of a semiconductor material on a curved surface of a substrate. The substrate can be extruded prior to coating and can be cut to predetermined dimensions before or after coating. The coating can be formed by depositing a layer of a semiconductor material on a portion of a surface of the substrate. Forming the coating can include generating a substantially uniform thickness layer on a portion of the surface of the substrate. Forming a coating on the surface can also include depositing a chemical vapor on the surface. The surface can be a curved inner surface of the substrate or a curved outer surface of the substrate. The method can include directing a deposition element adjacent to an inner surface of the curved substrate and depositing a chemical vapor on the surface.

In another aspect, a method of generating electricity includes exposing a photovoltaic cell having a curved surface to a light source. The method can include collecting charge generated by exposing the photovoltaic cell to the light source and may include transporting the charge to an electrical demand source. The electrical demand source can include a charge storage device.

A system for converting light into electrical energy can include a plurality of photovoltaic cells, with at least one of the photovoltaic cells having a curved surface, and an electrical connection between at least two of the photovoltaic cells. The system can include a storage device for storing electrical energy electrically connected to the photovoltaic cells. In addition, the system can includes a mounting apparatus for securing the photovoltaic cells to a light exposure surface. The mounting apparatus can include electrical connections for each of the photovoltaic cells integral to the apparatus. The light exposure surface can include a roof. The system can also include a protective overlayer surrounding the curved photovoltaic cells. Each photovoltaic cell of the system can include a substrate that has an annular cross section and includes a first end, a second end opposite the first end, an inner surface connecting the first end and the second end, and an outer surface opposite the inner surface. The system can also include a bottom semiconductor layer and a top semiconductor layer on a surface of the substrate. There can be a first electrical connection connected to the top semiconductor layer and a second electrical connection connected to the bottom layer. Each cell can have a first end that forms a seal around the first electrical connection and a second end that forms a seal around the second electrical connection.

The details of one or more embodiments are set forth in the accompanying drawings and the description below. Other features, objects, and advantages will be apparent from the description and drawings, and from the claims.

### DESCRIPTION OF DRAWINGS

FIG. 1 is a perspective view of a curved photovoltaic cell coated on an inner surface.

FIG. 2 is a perspective view of a curved photovoltaic cell coated on an outer surface.

FIG. 3 is a cross-section of a curved photovoltaic cell coated on an inner surface.

FIG. 4 is a cross-section of a curved photovoltaic cell coated on an outer surface.

FIG. 5 is a top view of a system of curved photovoltaic cells.

FIG. 6 is an end perspective view of a system of curved photovoltaic cells.

FIG. 7 is a schematic of an example of a system for deposition of semiconductor material on a glass substrate as the substrate is being formed.

FIG. 8 is a schematic of a system for deposition of semiconductor material on a glass substrate as the substrate is being formed.

### DETAILED DESCRIPTION

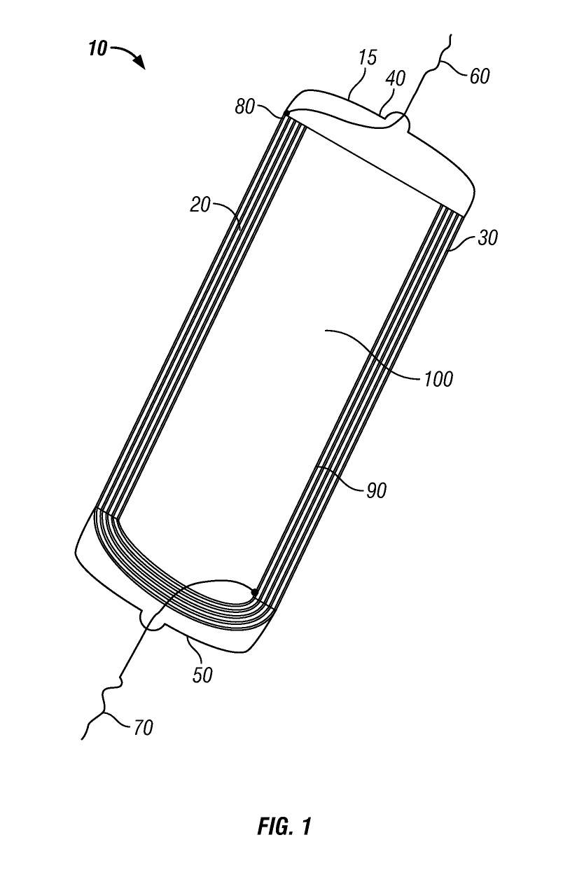

Referring to FIG. 1, a photovoltaic cell 10 has layers of semiconductor material 20 on a curved inner surface 30 of the cell 10. The semiconductor material 20 can coat the portion of the inner surface 30 of a curved substrate 15 of the photovoltaic cell 10 in multiple layers. The photovoltaic cell 10 has a first end 40 and a second end 50 that can be sealed around electrical conducting elements 60 and 70. The electrical conducting elements 60 and 70 are in electrical contact with a bottom 80 and a top layer 90 of the semiconductor material 20 respectively. Sealed ends 40 and 50 in combination with inner surface 30 form a sealed chamber 100 that contains the semiconductor material 20. The sealed chamber 30 can be evacuated and filled with an inert gas such as argon, nitrogen or helium or a combination of inert gases.

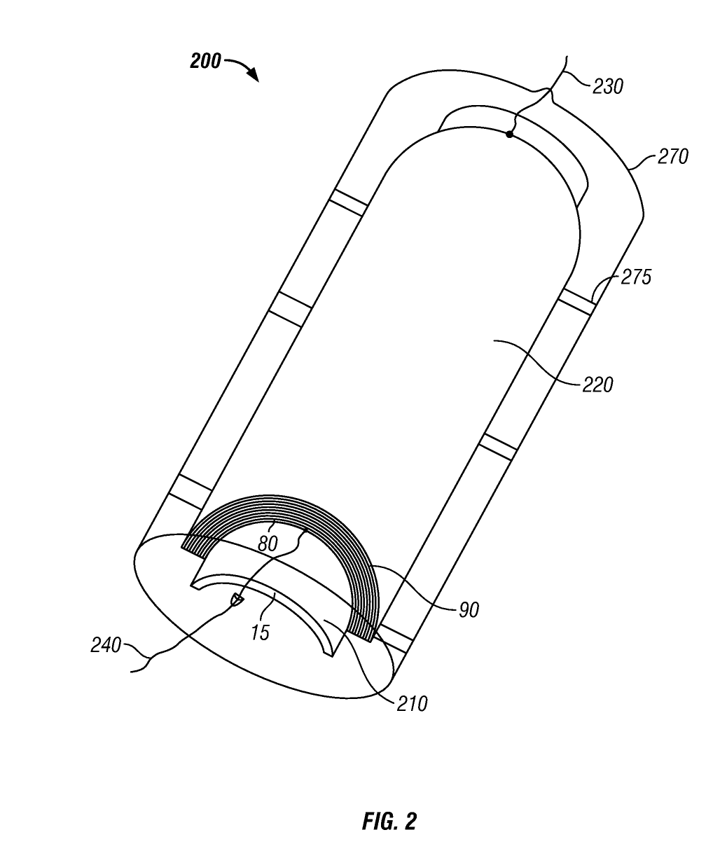

Referring to FIG. 2, a curved photovoltaic cell 200 has a curved surface 210 with layers of semiconductor material 220 deposited on at least a portion of the outer surface 220 of the substrate 15. Electrical conducting elements 230 and 240 can be attached to the top layer 90 and the bottom layer 80 of the semiconductor material. A protective tube 270 can encase the photovoltaic cell 200 to protect the semiconductor material 220. The protective tube can include separators 275 that keep the photovoltaic cell 200 from resting on the semiconductor material 220. The separators 275 can be of any appropriate design, for example, the separators can be bars that connect to an uncoated portion of the substrate.

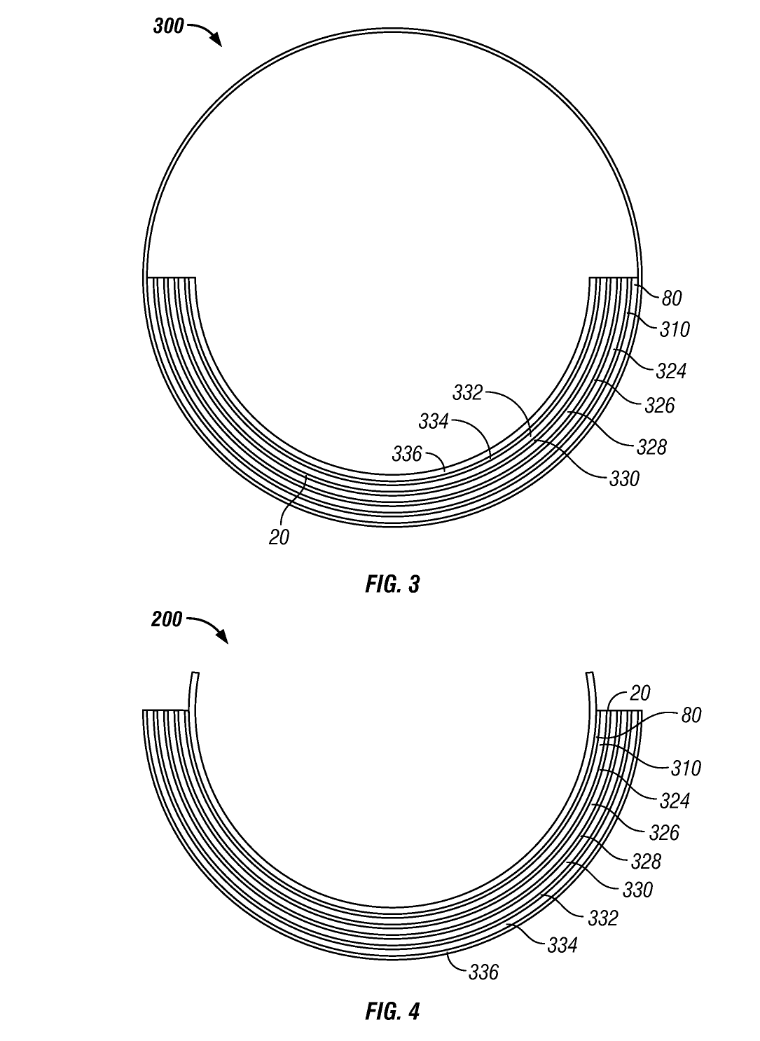

Referring to FIG. 3 and FIG. 4, cross-sections 300 and 400 of curved photovoltaic cells 10 and 200 have multiple layers of semiconductor material 20 and 220 deposited thereon. The semiconductor material 20 can include multiple layers. In an example of a common photovoltaic cell, the multiple layers can include: a tin oxide layer 80, a silicon dioxide layer 310, a doped tin oxide layer 324, a cadmium sulfide layer 326, a cadmium telluride layer 328, a zinc telluride layer 330, a nickel layer 332, an aluminum layer 334, and another nickel layer 336. This example illustrates that the bottom layer 80 can be a conductive material such as a transparent conductive material including a transparent conductive oxide. One intermediate layer can be a buffer layer 310 that is composed of, for example, silicon dioxide. Other intermediate layers can be, for example, binary semiconductors such as a group II-VI semiconductor. An example of this would be a layer of CdS followed by a layer of CdTe. A top layer can cap off the intermediate layers and can be made of metal such as nickel or aluminum.

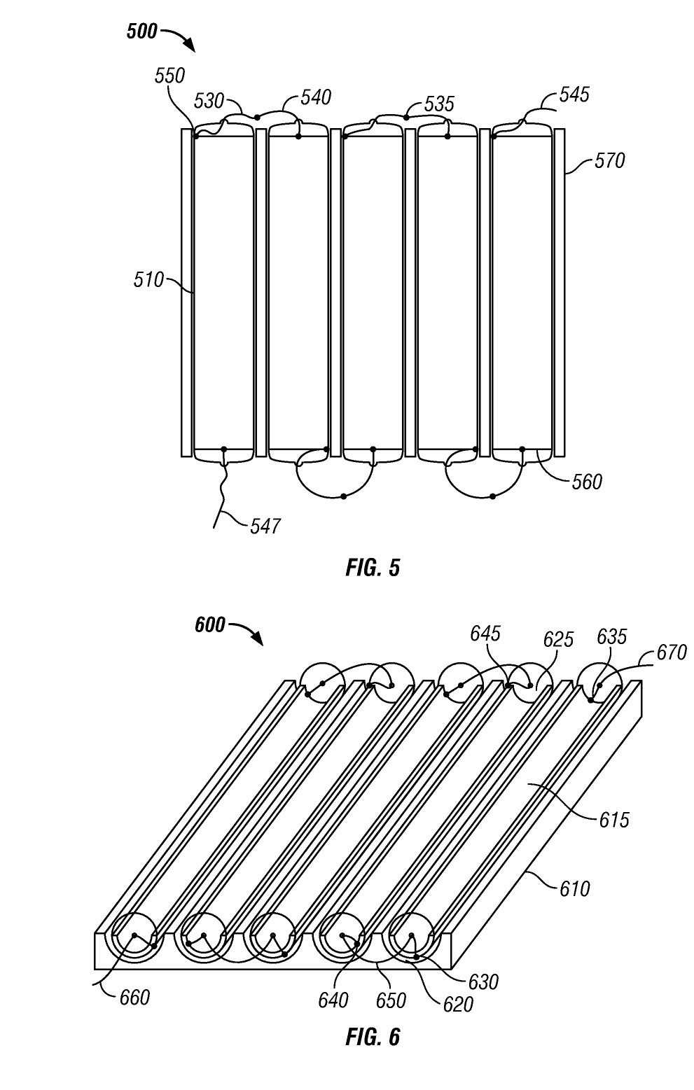

Referring to FIG. 5, a top view of a photovoltaic system 500 is composed of multiple curved photovoltaic cells 510 bundled together. Each photovoltaic cell can be connected in series to an adjacent cell via electrical conducting elements 530 or 540 and electrical connector 535 which connect alternating bottom 550 and top layers 560 of the photovoltaic cells 510 to form a circuit for the photovoltaic cells. End electrical conductors 545 and 547 can be connected to an electrical storage device, or to an electrical demand source. The mounting assembly 570 can hold each of the individual cells 510 and can protect them from the elements. The mounting assembly can consist of multiple parts including mounting elements for mounting the cells to a light exposure surface such as a roof, cell holding elements 580 for securing the cells to the mounting assembly and protection elements 590 for protecting the cells from environmental conditions. The cell holding elements can be integral to the individual slots or can be a function of the formation of the slots themselves. For example, a cell holding element could be one or multiple straps or brackets that can be placed over the cells and connected to the mounting assembly to hold the cells in place. Alternatively, the individual cell slots could be arranged such that the ends of the cells slide into recessed portions that hold the cells in place by preventing the cell ends from sliding out of the slot. Such a recessed portion could be a quick connect/disconnect slot for easy installation and change out of an individual solar cell. The mounting assembly could include wiring for each slot and could provide electrical connections to facilitate collection of the electricity generated by the cells. The wiring could be provided to avoid interruption of current flow during change out of individual cells. The mounting assembly can be made from lightweight durable materials. Such materials could include various rigid plastics and resins or non-conductive lightweight metals, wood or other similar materials.

Referring to FIG. 6, a perspective view of a system of multiple curved photovoltaic cells 600 has a mounting assembly 610. A plurality of curved photovoltaic cells 600 can be fitted into individual spacings 620 in the mounting assembly 610. The mounting assembly 610 can be a constructed from lightweight materials such as polymers, plastics, non-conducting metals, composites, wood or other similar materials. The curved photovoltaic cells 600 can be electrically connected in series or in parallel with alternating connections from the top layer of one cell to the bottom layer of an adjacent cell. Specifically, connection 630 is connected to the bottom layer of the individual photovoltaic cell 615, while connection 635 at the other end of the photovoltaic cell 615 is connected to the top layer connection 630 is connected to the adjacent photovoltaic cell 625 via connector 650. Connection 640 at the opposite end of connector 650 is connected to the top layer of cell 625. Connection 645 at the opposite end of cell 625 is connected to the bottom layer and begins the cycle again by connecting to top layer of the next adjacent cell. At the each end of the array are conducting wires 660 and 670, which connect to the demand or storage device.

The curved photovoltaic cells can be of various polygonal shapes in cross section and can be cut to a specific length during the formation process. For example, the photovoltaic cells, can have a cross section that is circular, or a half circle, or triangular with one side curved, or n-sided with at least one side and possibly multiple sides being curved with semiconductor material deposited in layers on at least one curved surface. They can be formed from a variety of materials including glass, low iron glass and low expansion glass as defined by the industry, and borosilicate glass. Photovoltaic cells can be formed on annular or solid materials. The semiconductor layers can be deposited on them using a variety of techniques including chemical vapor deposition and vapor transport deposition. They can be encased in a protective coating or enclosure to prevent damage to the semiconductor surface.

A process for making a photovoltaic device is performed by establishing a contained environment or chamber heated in a steady state during the processing to a starting temperature in a range above about 550° C., and preferably in the range of about 800-1000° C. for the temperature of the glass extruder/distributor during initial formation of the glass substrate from the melted glass. The environment can be kept under vacuum or an inert atmosphere to prevent exposure and possible weakening of the hot substrate due to water vapor exposure. For example, glass fully formed and cooled in the absence of water vapor will have a more desirable and higher modulus of rupture. Referring to FIGS. 1-4, the substrate 15 can be directly extruded from a local source of hot substrate, or can be pre-formed. The substrate 15 can be cut to the desired processing dimensions following the extrusion step. For example, the substrate 15 can be cut into any length required for specialized application, or can be cut into standard lengths such as 2 foot or 4 foot lengths for off the shelf devices. Alternatively, the substrate 15 can be kept in 10-20 foot lengths for processing and later cutting. The substrate 15 can be pre-formed or extruded into a solid curved or annular curved substrate, where either the solid curved or the annular curved substrate has a polygonal cross-section with at least one curved surface. The substrate 15 when formed with a circular cross-section can have a diameter greater or smaller than about 0.75 inches.

After formation and sizing, the substrate 15 is ready for deposition of the bottom conductive layer 80. Deposition of the bottom layer 80 on the inner surface 30 of the substrate 15 involves forming a substantially uniform layer of a conductive material on the surface of the substrate. This layer can be a transparent conductive material including a transparent conductive oxide. An example of a typical conductive oxide is tin oxide. The deposition on the inner surface 30 can be accomplished by passing the annular substrate 15 around a vapor deposition element at a fixed rate or alternatively inserting a vapor deposition element into the annular substrate 15 at a fixed rate. The rate can be determined based upon the desired thickness of the deposition layer and would be a function of the vapor supply rate and the velocity of the deposition element with respect to the substrate 15. The substrate 15 could be stationary or moving while the deposition is taking place and could be part of a continuous manufacturing system where the substrate 15 is kept in the contained environment and conveyed to different stations for different treatment.

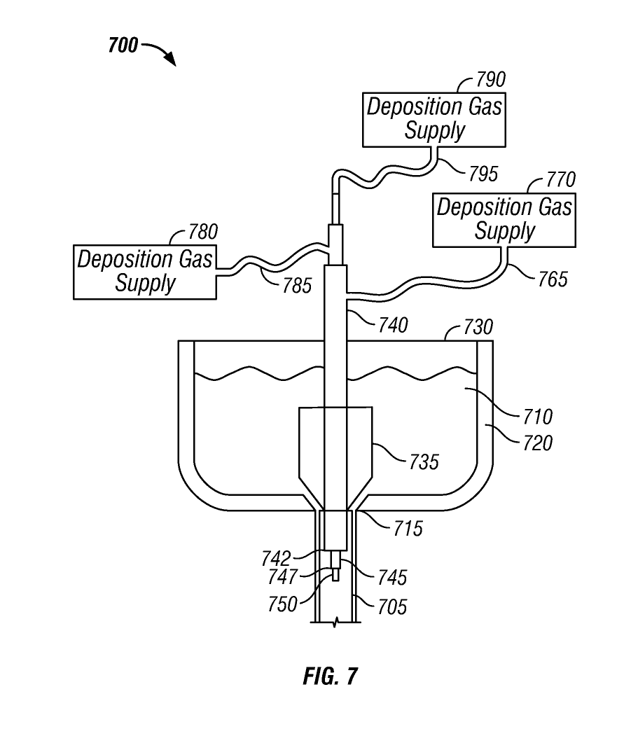

Alternatively, deposition of the layers can be performed as the glass substrate is being formed and sized. FIG. 7 provides an example of an apparatus 700 for accomplishing this. A hot melted glass supply 710 in a melted glass reservoir 720 has an orifice 715 for formation of a glass substrate 705 from the melted glass. The glass substrate 705 can have any polygonal cross-section or may be in the form of a ribbon or a half-tube. Extending through the melted glass reservoir top 730 and through the orifice plug 735 is an annular depositor 740 which deposits a first deposition layer on the substrate. Annular depositor 740 extends through the melted glass reservoir 720, out the top 730 of the reservoir and connects to an insulated heated flexible deposition gas supply line 765 that provides enough flexibility and length for the depositor to be raised and lowered both to deposit gas and to open the orifice plug 735. The supply line 765 is connected to an external source of the deposition gas or gases 770. The deposition layer can be deposited on a portion of the substrate surface or can be deposited across the entire substrate surface, by regulating the extent of the annulus through which gas may pass.

A second depositor 745 extends from within depositor 740 beyond the first deposition end 742 to a second deposition end 747 to deposit a second deposition layer on a surface of the substrate. The outer wall of the second depositor is spaced away from the inner wall of the first depositor creating the annular space through which the first deposition gas flows. The second deposition gas similarly travels through the annular space between the inner wall of the second depositor and the outer wall of a third depositor 750. This deposition gas also comes from an external supply 780 via heated, insulated flexile supply line 785. Similarly, a third depositor 750 extends from within the second depositor 745 to deposit a third deposition gas. For the purpose of this example there are only three separate deposition gas streams, and thus three depositors though more or less of each can be used depending on the number of layers to be deposited. The third deposition gas supply 790 connects via a heated, insulated flexible line 795 to the third depositor 750. Since this depositor is the last one in this example, the flow is not annular and thus the diameter can be smaller for the same volume of flow. When supplying gases, the external gas supplies and individual depositors can supply gas mixtures, pure gases, or multiple gases that mix at the deposition end of the individual depositors. This can be accomplished using different supply line and deposition line configurations than are shown in this example. The deposition ends of the depositors can have varying shapes and attachments to facilitate deposition of a homogenous layer or layers on the substrate including various spray mechanisms and air mixers.

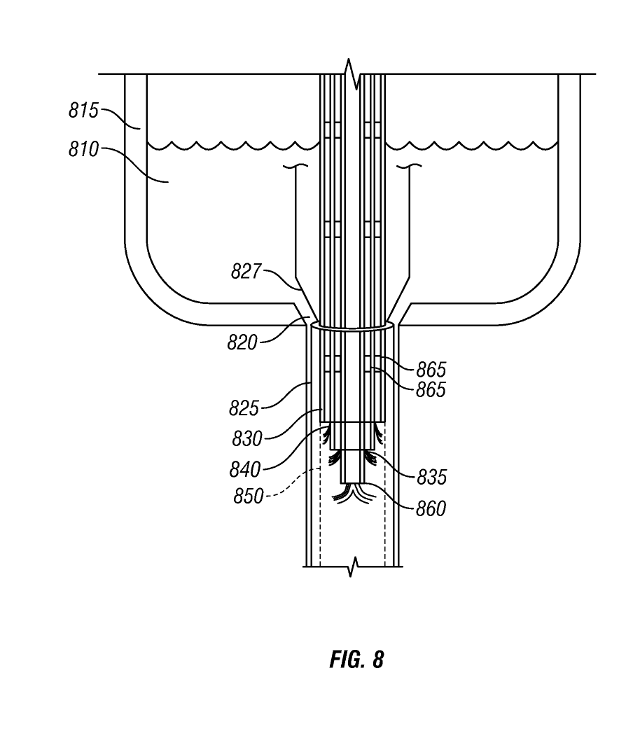

Referring to FIG. 8, a hot melted glass supply 810 in a melting reservoir 815 has an orifice 820 for formation of glass substrate 825 that can be sealed by plug 827. The substrate 825 can be formed around the outer surface 830 of an annular depositor 840 which deposits a first deposition layer on the inner surface 850 of the forming substrate 825. A second annular depositor 835 is shown depositing a second deposition layer onto the inner surface 850 from an annular position within depositor 840. A third annular depositor 860 is shown depositing a third deposition layer onto the inner surface 850 from an annular position within depositor 835. Additional annular depositors are possible though not shown. The annular depositors are spaced apart form each other and supported within the ultimate structure using, for example, spacers 865 to ensure adequate flow volume of deposition gas through each annulus. By applying the layers to the glass as it is forming, the deposition can occur at the optimum temperature and the glass is at it's cleanest when it is initially forming. The annular depositors can be configured to deposit on the whole inner surface, or a portion of the inner surface. Additionally, other configurations using, for example, fins or half-annular blocks can be used to prevent or facilitate gaseous mixing prior to deposition.

The bottom conductive layer 80 can be deposited on an inner surface 30 of the substrate 15 using a method of chemical vapor deposition in which the deposition element is moved within the annular region of the substrate 15 at a constant rate in order to form a uniform layer on the inner surface 30. The deposition element can be designed to coat a portion of or the entire inner perimeter of an annular substrate 15. Similarly, a solid substrate 15 can be coated with the bottom layer 80 using a method of chemical vapor deposition along the curved surface of the substrate 15. The perimeter, or a portion thereof, can be coated by rotating the substrate 15 as it moves past the deposition element.

The bottom layer 80 can be a film of tin oxide applied by atmospheric pressure chemical vapor deposition approximately 0.04 microns thick to improve the optical quality. A buffer layer can be applied that includes a silicon dioxide film 310 and is applied by atmospheric pressure chemical vapor deposition to a thickness of 0.02 microns over the tin oxide film to provide a barrier. Next, another tin oxide film 324 that is 0.3 microns thick and fluorine doped is applied over the silicon dioxide film. This second film of tin oxide functions as a reflective film in architectural usage with the fluorine doping increasing the reflectivity and as an electrode for the photovoltaic device as is hereinafter more fully described.

After the bottom layers have been applied, the substrate 15 can be transported from the chemical vapor deposition zone, to a vapor transport deposition zone. Additional conductive layers can be added at this point. The system includes a suitable heater for heating the substrate 15 to a temperature in the range of about 450 to 640° C. in preparation for semiconductor deposition. The substrate 15 is next transported through a series of deposition stations. The number of stations depends on the semiconductor material to be deposited but can include three deposition zones for depositing three separate semiconductor material layers. More specifically, the first deposition station can deposit a cadmium sulfide layer 326 that can be 0.05 microns thick and acts as an N-type semiconductor. The second deposition station can deposit a cadmium telluride layer 328 that is 1.6 microns thick and acts as an I-type semiconductor. Thereafter, the third deposition station can deposit another semiconductor layer 330 which can be 0.1 microns thick and can be zinc telluride that acts as a P-type semiconductor. The first and second semiconductor layers 326 and 328 have an interface for providing one junction of the N-I type, while the second and third semiconductor layers 328 and 330 have an interface for providing another junction of the I-P type such that the resultant photovoltaic cell is of the N-I-P type. These interfaces normally are not abrupt on an atomic scale, but rather extend over a number of atomic layers in a transition region. This system is not limited to the specific semiconductor materials identified above, and will function using a variety of such materials known to those skilled in the art.

After deposition of the semiconductor layers, the substrate 15 can undergo a rapid cooling process to strengthen the glass. This process can include rapid blowing of nitrogen or another inert gas inside and outside of and normal to the substrate to cool it, providing compressive stress that strengthens the glass.

After the rapid cooling step, a sputtering station receives the substrate 15 and deposits a nickel layer 332 over the semiconductor layers. This nickel sputtering is preferably performed by direct current magnetron sputtering and need only be about 100 angstroms thick to provide a stable contact for a subsequent deposition. Thereafter, the substrate 15 is transferred to a sputtering station that deposits an aluminum layer 334 that is 0.3 microns thick over the nickel layer 332 to act as an electrode on the opposite side of the semiconductor layers as the tin oxide film 80, which acts as the other electrode. The aluminum layer 334 is deposited by in-line multiple cathode, direct current magnetron sputtering. Thereafter the substrate 15 is received by another sputtering station that applies another nickel layer 336 over the electrode aluminum layer to prevent oxidation of the aluminum layer 334.

After the sputtering is complete, electronic conducting elements 60 and 70, for example, wire leads, are attached to the two electrode layers 80 and 334 one at each end of the substrate 15. For the annular substrate 15 with semiconductor material on the inner surface 30 of the substrate, the annulus is evacuated using a vacuum. The ends of the substrate 15 are melted to form a seal round each of the electronic conducting elements 60 and 70 and an inert gas is inserted into the evacuated annulus. The electronic conducting elements 60 and 70 can be used to connect one cell to another in series or in parallel as part of a photovoltaic system, or can connect individually to a storage device for storing the electricity, or can connect directly to an electrical demand source. The electronic conducting elements may come from alternate ends of the each individual cell or both may come from one sealed end of the cell. The conducting elements may be arranged such that they form a standardized end connection for easy change out of individual cells. The mounting assembly can be configured to receive the specific connection types and can serve to provide electrical connections between the individual cells, including continued service when individual cells are malfunctioning or have failed. The mounting assembly may then serve to distribute the generated electricity to a storage device or a demand source.

When the semiconducting layers are placed on the outer surface 220 of the curved substrate 15, the electronic conducting elements 60 and 70 can be attached to the appropriate electrode layers and then the entire cell can be encased in a transparent protective tube or can be covered with a transparent protective layer. The transparent protective layer or tube can also serve to help form a standardized connection for the cell. As such, a photovoltaic system or array can include both cells with the semiconductor material on the inner curved surface and on the outer curved surface or the substrate

As shown in FIGS. 5 and 6, multiple cells can be brought together and connected in electrical series to form a photovoltaic array capable of generating low cost electrical power. The individual cells are connected to each other electrically using the electrical conductors 530 and 540 and electrical connector 535, and can be held in a mounting assembly for direct exposure to a light source including the sun. The mounting assembly can be any assembly capable of holding the curved photovoltaic cells and exposing them to a light source including the sun, and can incorporate lightweight materials such as polymers, resins, non-conductive metals and composites into the design. The mounting assembly can provide for a modular system of use in which the photovoltaic cells have a standardized electrical connection that connects to the mounting assembly that distributes the generated electricity. Multiple mounting assemblies can be configured to attach to attach to each other.

The entire contained environment can be heated using electrical resistance heaters, with the temperature controllable at each zone. When operated as a continuous manufacturing process, the substrate 15 can be transported using substrate holders designed specifically for the placement of the semiconductor layers (inner or outer surface). Such transport can be accomplished using a roll conveyor type mechanism or any other conveyancing means suitable for the processing environment.

In another embodiment, a low reflective coating could be added to the outer surface of the substrate to increase efficiency by allowing more of the incident sunlight to penetrate. Examples of such coatings include a variety of vacuum deposited thin films commonly used in the photography industry to reduce reflection. Other examples include a thin film of MgF₂, or a thin film sol gel application of silicon powder to make a coating at 1.23 index of refraction

A number of embodiments have been described. Nevertheless, it will be understood that various modifications may be made without departing from the spirit and scope of the invention. For example, other semiconductor materials can be used, and different mounting means can be used. Accordingly, other embodiments are within the scope of the following claims.

What is claimed is:

1. A solar cell assembly comprising a plurality of elongated solar cells, wherein each elongated solar cell in said plurality of elongated solar cells comprises:
(i) a rigid tube-shaped conductive core, wherein said rigid tube-shaped conductive core is made of plastic or glass;
(ii) a back-electrode circumferentially disposed on said rigid tube-shaped conductive core;
(iii) a semiconductor junction circumferentially disposed on said back-electrode; and
(iv) a transparent conductive layer circumferentially disposed on said semiconductor junction, wherein elongated solar cells in said plurality of elongated solar cells are arranged in a parallel or a near parallel manner thereby forming a planar array having a first face and a second face, wherein the solar cell assembly is configured to receive direct light from a side of said solar cell assembly that includes said first face of said planar array and a side of said solar cell assembly that includes said second face of said planar array.

2. The solar cell assembly of claim 1, wherein the back-electrode is a transparent conducting oxide.

3. The solar cell assembly of claim 1, wherein the semiconductor junction comprises an absorber layer made of cadmium telluride and a window layer made of cadmium sulfide.

4. The solar cell assembly of claim 1, wherein the diameter of a cross-section of a solar cell in said solar cells is between 0.5 millimeters (mm) and 20 mm.

5. The solar cell assembly of claim 1, further comprising: a transparent electrically insulating substrate that covers all or a portion of said first face of said planar array; and a transparent insulating covering disposed on said second face of said planar array, thereby encasing said plurality of elongated solar cells between said transparent insulating covering and said transparent electrically insulating substrate.

6. The solar cell assembly of claim 1, wherein said semiconductor junction is a homojunction, a heterojunction, a heteroface junction, a buried homojunction, or a p-i-n junction.

7. The solar cell assembly of claim 1, wherein there is a buffer layer disposed between said semiconductor junction and said transparent conductive layer.

8. The solar cell assembly of claim 7, wherein the buffer layer is formed by an undoped transparent oxide.

9. The solar cell assembly of claim 8, wherein the buffer layer is made of zinc oxide, indium-tin-oxide, or a combination thereof.

10. The solar cell assembly of claim 1, wherein the semiconductor junction comprises: an inner coaxial layer; and an outer coaxial layer, wherein said outer coaxial layer comprises a first conductivity type and said inner coaxial layer comprises a second, opposite, conductivity type.

11. The solar cell assembly of claim 1, wherein said transparent conductive layer is made of tin oxide SnOₓ, with or without fluorine doping, indium-tin oxide (ITO), zinc oxide (ZnO) or a combination thereof.

12. The solar cell assembly of claim 1, wherein two or more elongated solar cells in said plurality of elongated solar cells are electrically connected in parallel.

13. The solar cell assembly of claim 1, wherein two or more elongated solar cells in said plurality of elongated solar cells are electrically connected in series.

14. The solar cell assembly of claim 1, wherein the plurality of elongated solar cells are arranged such that one or more elongated solar cells in said plurality of elongated solar cells do not contact adjacent elongated solar cells.

15. The solar cell assembly of claim 1, wherein a solar cell in the plurality of solar cells has an elliptical cross-section.

16. The solar cell assembly of claim 1, wherein a solar cell in the plurality of solar cells has a cross-section that is generally circular.
